(19) United States
(12) Patent Application Publication
(10) Pub. No.: US 2026/0068237 A1
(43) Pub. Date: Mar. 5, 2026

(54) GATE-ALL-AROUND FIELD EFFECT TRANSISTOR HAVING TRENCH INNER-SPACER, AND METHOD FOR MANUFACTURING SAME

(71) Applicant: SAMSUNG ELECTRONICS CO., LTD., Suwon-si (KR)

(72) Inventors: Rock Hyun BAEK, Pohang-si (KR); Jin Su JEONG, Pohang-si (KR)

(73) Assignee: SAMSUNG ELECTRONICS CO., LTD., Suwon-si (KR)

(21) Appl. No.: 19/144,182

(22) PCT Filed: Dec. 30, 2022
(86) PCT No.: PCT/KR2022/021740

§ 371 Date: Jun. 27, 2025

(30) Foreign Application Priority Data
Dec. 1, 2022 (KR) 10-2022-0165880

(51) Int. Cl. H10D 62/10; H10D 30/00; H10D 30/01; H10D 30/43; H10D 62/83; H10D 64/66

(52) U.S. Cl. CPC H10D 62/102; H10D 30/014; H10D 30/0191; H10D 30/43; H10D 30/502; H10D 62/121; H10D 62/83; H10D 64/675

(57) ABSTRACT

The present disclosure discloses a gate-all-around field effect transistor which not only can suppress the occurrence of punch through in the substrates and direct leakage of current from the source region/drain region into the part under the channels, but also can facilitate heat release of the substrate, and minimizes the occurrence of device defects due to misalignment between the trench inner spacers and the device by forming trench inner spacers (TISs) and thus preventing source region/drain region impurities from diffusing into the substrate, and a method for manufacturing the same.

### TECHNICAL FIELD

The present disclosure relates to a gate-all-around field effect transistor having trench inner spacers and a method for manufacturing the same.

### BACKGROUND ART

Various 3D structure devices such as FinFET and gate-all-around field effect transistor (GAAFET) are currently being studied in order to overcome the short-channel effect by developing a 3D structure semiconductor device.

Among them, a 3D gate-all-around field effect transistor (GAAFET) means a structure in which all four sides of channels are surrounded by gates. Unlike the FinFET, in the gate-all-around field effect transistor (GAAFET), it is possible to stack channels. Therefore, although the number of channels is increased, an area of the lower end portion that is occupied by an FET is not increased. Thus, the gate-all-around field effect transistor (GAAFET) is advantageous in realizing miniaturization and in easily controlling the width and the number of channels.

In a manufacturing process of a conventional GAA transistor, a recess etching process is performed to form a source region/a drain region. In such an etching process, an over-etch phenomenon occurs unintendedly due to process variation. At this time, T_{SD} means the over-etched source region/drain region recess thickness.

The present inventors have proposed such a problem and a solution thereto in NSFETs through Non-Patent Documents 1 and 2. These documents disclose that the deeper the T_{SD}, the more impurities in the source region/drain region diffuse toward the substrate, and accordingly, a large amount of leakage current occurs at the portion under the channel that is not controlled by the gate due to the punch-through phenomenon.

The deeper the T_{SD}, the more leakage current and parasitic capacitance occur. In particular, the documents disclose that the leakage current caused by the T_{SD} causes a serious increase in static power consumption and, in severe cases, causes a serious problem in that the GAAFET cannot function as a semiconductor device.

Through Patent Document 1, in order to prevent leakage current due to over-etched source region/drain region recesses, the present applicant has proposed a BOX Scheme technology for buried oxide (BOX) that deposits an insulator (SiO₂ or Si₃N₄) under the source region/drain region. However, when an insulator is deposited under the source region/drain region in such a BOX scheme technology, it is difficult to release heat generated in a device through a Si substrate due to the thermal conductivity of the insulator lower than that of Si, resulting in deterioration of the device.

### RELATED ART DOCUMENT

### Patent Document

Korea Patent No. 10-2133208 B1 (published on Jul. 14, 2020)

### Non-Patent Documents

J.-S. Yoon, J. Jeong, S. Lee, and R.-H. Baek, Punch-through-stopper Free Nanosheet FETs with Crescent Inner-spacer and Isolated Source/Drain, 14 Mar. 2019, IEEE Access vol. 7, p 38593-38596
J. Jeong, J.-S. Yoon, S. Lee and R.-H. Baek, Comprehensive Analysis of Source and Drain Recess Depth Variations on Silicon Nanosheet FETs for Sub 5-nm Node SoC Application, February 2020, IEEE Access, vol. 8, p 35873-35881

### DISCLOSURE

### Technical Problem

The present applicant has studied devices having various structures that can be manufactured without significant change in the existing process and can effectively prevent the above-described leakage current and at the same time secure the heat release effect through the substrate. As a result, the present applicant has found that, when trench inner spacers, which are connected to inner spacers, are formed in a substrate or a punch through stopper (PTS), the leakage current could be suppressed regardless of the over-etched T_{SD}, and the heat release effect through the substrate could be simultaneously secured compared to the BOX Scheme technology.

Accordingly, an object of the present disclosure is to provide a gate-all-around field effect transistor having trench inner spacers and a method for manufacturing the same.

### Technical Solution

The field effect transistor according to the present disclosure is a gate-all-around field effect transistor (hereinafter referred to as ‘GAAFET’), and may be a nanosheet gate-all-around field effect transistor as an example. The GAAFET according to the present disclosure is a technology capable of simultaneously solving leakage current occurring under the channels and a problem of obstructing release of heat through the substrate. This is achieved by forming trenches spaced apart from each other by a certain distance on a substrate or a punch through stopper (hereinafter referred to as ‘PTS’), and forming trench inner spacers (hereinafter referred to as ‘TISs’) such that the TISs are extended from inner spacers located between the source region/drain region and the lowermost gate stack to the insides of the trenches, and through this structure, robustness of source region/drain region recess process variables can be secured in the GAAFET device.

In the present disclosure, TISs may be formed in various forms. Since the trench patterning process for TISs formation is performed at the beginning of the manufacturing process of the device, consistency of patterning may be precisely controlled. The TISs can be transformed into various forms.

In the present disclosure, in order to form TISs, after trench patterning is performed to form two trenches through etching on a substrate or PTS, channels, a gate, and an outer spacer are formed, and then vertical etching of the channels and sacrificial layers may be performed in order to form a source region/drain region. Thereafter, after selective etching of the sacrificial layers contacting the channels is performed, inner spacers may be formed, and TISs may be formed to extend to the insides of the trenches.

In the present disclosure, trenches formed during the trench patterning may be formed by etching a corresponding region vertically below the outer spacer on the substrate or the PTS or a region separated or shifted therefrom by a predetermined distance.

In the present disclosure, the separation distance between the two trenches may be the same as or different from the widths of the gate stacks.

Further, in the present disclosure, the widths of the trenches may be the same as or different from the width of the outer spacer or the inner spacers.

However, when forming the trenches as described above in the present disclosure, it may be difficult to implement the trenches as desired due to a large aspect ratio in an actual process. Therefore, in the present disclosure, ease of implementation is improved by forming trenches to have a wider width than the width of the spacer or forming two trenches with a separation distance wider than the widths of the gate stacks during trench patterning.

In the present disclosure, when the trenches are formed to have a wider width than the width of the spacers as described above, if necessary, Si epitaxial layers are grown on the inner surface of the trenches, and thus the width of the trench inner spacers (TISs) to be located inside the trenches may be precisely adjusted.

In the present disclosure, the sacrificial layers may be grown after the trench patterning as described above. At this time, one or more empty space voids may be formed in the sacrificial layers. However, the entirety or a portion of the void region may be etched and removed during an additional etching process for forming TISs thereafter, and then, the void does not affect the performance of the GAAFET by forming trench inner spacers (TISs) inside the trenches.

In the present disclosure, the trenches included in the GAAFET fabricated by the above process may each have a structure including first regions formed to extend in a longitudinal direction vertically below the substrate or PTS and second regions which are located below the first regions and of which a cross section is formed to extend in a direction orthogonal to the longitudinal direction, that is, a form in which the XZ-axis cross section is an ‘L’ shape. In addition, the TISs positioned inside the trenches may fill the entirety or a portion of the first regions and/or the second regions of the trenches.

Various forms mentioned above can be combined with each other, and will be described below with several structures to help understanding. The structure described below is only one example and does not limit the structure presented in the present disclosure.

### Advantageous Effects

In the GAAFET device having trench inner spacers (TISs) according to the present disclosure, impurities in the source region/drain region are diffused toward the substrate by an over-recess during the etching process for forming the source region/drain region so that the leakage current which occurs under the channels that the gate cannot control can be prevented.

Further, as the source region/drain region recesses become deeper, the depth of the trench inner spacer also becomes deeper at the same time, so that there is robustness of source region/drain region recess process variables.

In addition, a technique for preventing leakage current at the part under the channels by depositing a dielectric layer on the bottom of the source region/drain region has been previously invented, but the present technique has an advantage in that heat is more easily released to the substrate compared to the previous invention.

Such a technique can be applied to all semiconductor products that utilize 3D GAAFET devices, and it is possible to expect an increase in production yield and a reduction in costs due to reduced power consumption due to reduced leakage current and robustness of source region/drain region recess process variables.

In addition, since the trench patterning process for forming the trench inner spacers (TISs) is performed at the beginning of the manufacturing process of the device, consistency of patterning can be precisely controlled so that there is an advantage in that the possibility and completeness of technology application are very high. In addition, since other processes can utilize existing ones as they are, the present technique has high applicability.

### BRIEF DESCRIPTION OF DRAWINGS

FIG. 1 is a cross-sectional view showing a GAAFET according to a first embodiment of the present disclosure.

FIG. 2 is a cross-sectional view showing a GAAFET according to a second embodiment of the present disclosure.

FIG. 3 is a cross-sectional view showing a GAAFET according to a third embodiment of the present disclosure.

FIG. 4 is a cross-sectional view showing a GAAFET according to a fourth embodiment of the present disclosure.

FIGS. 5 to 21 are views showing processes for manufacturing a GAAFET device according to one embodiment of the present disclosure.

### BEST MODE FOR CARRYING OUT THE INVENTION

The present disclosure relates to a gate-all-around field effect transistor (GAAFET) in which trenches spaced apart from each other by a predetermined distance are located on a substrate or a punch through stopper (PTS), and which includes trench inner spacers (TISs) extending from inner spacers positioned between a source region/a drain region and a lowermost gate stack to the insides of the trenches.

Describing the structure of the GAAFET according to the present disclosure from the bottom thereof, the GAAFET according to the present disclosure includes a substrate 100 or PTS 103 in which a first trench 259 and a second trench 259′ positioned to be spaced apart by a predetermined distance are formed, source region 201/drain region 202 which are formed to be spaced apart from each other on the top of the substrate 100 or PTS 103, a series of gate stacks (260) between the source region 201/drain region 202, and a series of channels N1, N2, N3, and 230 extending under the gate stacks 260 between the source region 201 and the drain region 202.

The GAAFET according to the present disclosure further includes an outer spacer 265 formed on the top and side surfaces of the uppermost gate stack 260, inner spacers S1, S2, 255, and 256 connected to the outer spacer 265 and formed between the source region 201/drain region 202 and the gate stacks 260, and TISs 257 and 257′ located inside the trenches 259 and 259′ and vertically connected to the lowermost inner spacer 256.

The trenches 259 and 259′ may include first regions A1 and A1′ of which cross sections are formed to extend in a first direction, which is a longitudinal direction vertically below the substrate 100 or PTS 103, and second regions A2 and A2′ which are positioned below the first regions A1 and A1′, and of which cross sections are formed to extend in a second direction orthogonal to the first direction. Here, the first direction may be an X-axis direction, and the second direction may be a Z-axis direction, but the directions are not limited thereto.

Widths w2 and w2′ of the second regions A2 and A2′ of the trenches 259 and 259′ may be equal to or wider than widths w1 and w1′ of the first regions A1 and A1′, preferably wider than the widths w1 and w1′ so that the cross-section of the trenches 259 and 259′ may have a groove structure having an ‘L’-shaped cross-section.

A separation distance g1 between the first trench 259 and the second trench 259′ may be equal to or wider than a width w3 of the gate stacks, and the separation distance wider than the width w3 may increase convenience in a manufacturing process.

The widths of the first regions A1 and A1′ of the trenches 259 and 259′ may be equal to or narrower than the width of the inner spacer 256.

TISs 257 and 257′ including first parts A10 and A10′ and second parts A20 and A20′ filling at least parts of the regions are located inside the first regions A1 and A1′ and the second regions A1 and A1′ of the trenches 259 and 259′. The first parts A10 and A10′ of the TISs 257 and 257′ may fill the entirety of the first regions A1 and A1′ of the trenches 259 and 259′ and may have a shape corresponding to the regions. The second parts A20 and A20′ may also fill the entirety of the second regions A2 and A2′ and may have a shape corresponding to the regions, but in terms of a realistic process, remaining parts 264 and 264′, which are unetched sacrificial layers, may remain on the lower portion of the second regions A2 and A2′, and the second parts A20 and A20′ of the TISs 257 and 257′ may be positioned on the remaining parts 264 and 264′.

Further, Si epitaxial layers 275 and 275′ may be positioned on the entirety or a portion of the inner surfaces of the trenches 259 and 259′, and at this time, the TISs 257 and 257′ may be located on the Si epitaxial layers 275 and 275′.

The present disclosure relates to a method for manufacturing a GAAFET having the structure described above.

The method according to the present disclosure may include steps of: (a) patterning trenches on the top of one side of a substrate or punch through stopper (PTS); (b) forming pluralities of channels and sacrificial layers alternately arranged on the substrate or punch through stopper (PTS); (c) forming two trenches positioned to be spaced apart from each other and patterning the channels and sacrificial layers; (d) forming a dummy gate and an outer spacer; (e) vertically etching the channels and sacrificial layers to form a source region/a drain region; (f) selectively etching a portion of the sacrificial layers in contact with the channels; (g) forming inner spacers and TISs; (h) forming the source region/drain region by a selective epitaxial growth process; (i) releasing the channels; (j) forming a replacement metal gate; and (k) performing WAC and MOL processes.

During the trench patterning, patterning may be performed such that an upper portion of one side of the substrate 100 or the PTS 103 is etched to form a first trench 259 and a second trench 259′.

During the trench patterning, the trenches 259 and 259′ may be etched so that the trenches 259 and 259′ have widths equal to or wider than a width of the outer spacer 265 or widths of the inner spacers 255 and 256 to be stacked afterwards.

During the trench patterning, the first trench 259 and the second trench 259′ may be etched so that the first trench 259 and the second trench 259′ are formed to be apart from each other by a distance equal to or wider than the width of the dummy gate 206 or the gate stacks 265 to be stacked afterwards.

The method may further include a step of selectively forming Si epitaxial layers 275 and 275′ on at least a portion of inner surfaces of the trenches 259 and 259′ before forming the channels and the sacrificial layers after the trench patterning.

When an over-recess occurs as much as the T_{SD} with respect to the substrate 100 or the PTS 103 due to process variables during vertical etching of the channels and the sacrificial layers, a partial region of the outer cross sections of the trenches 259 and 259′ may be etched. Accordingly, in the GAAFET structure to be finally manufactured, the trenches 259 and 259′ include the first regions A1 and A1′ and the second regions A2 and A2′ having different widths.

When the sacrificial layers are selectively etched, the entire sacrificial layers 205 present inside the trenches 259 and 259′ may be etched, but portions thereof may be unetched and may remain as the remaining parts 264 and 264′ in lower portions of the trenches 259 and 259′.

During forming of the TISs, an insulating material may be deposited the lower portions of the inner spacers 255 and 256 to the inner surfaces of the trenches 259 and 259′, or up to the upper portions of the remaining parts 264 and 264′ if the remaining parts 264 and 264′ are present to form the TISs 257 and 257′.

When over-etching occurs during the etching process for forming the source region/drain region, as portions of the outer cross sections of the wide trenches 259 and 259′ are also etched, a width difference may occur between the first parts A10 and A10′, which are the upper portions of the TISs 257 and 257′, and the second parts A20 and A20′, which are the lower portions thereof.

### MODE FOR CARRYING OUT THE INVENTION

The objects, other objects, features, and advantages of the present disclosure will be easily understood through the following preferred embodiments that will be described below with reference to the accompanying drawings. However, the present disclosure is not limited to the embodiments described herein and may also be embodied in other forms. Rather, the embodiments introduced herein are provided so that the disclosed content will be thorough and complete, and the spirit of the present disclosure will be sufficiently conveyed to those skilled in the art.

In the present specification, when a certain film (or layer) is referred to as being on other film (or layer) or substrate, it may be directly formed on the other film (or layer) or substrate, or a third film (or layer) may be interposed therebetween. In addition, the size, thickness, and the like of constituent elements in the drawings are exaggerated for clarity. In the present specification, the expression ‘and/or’ is used to mean including at least one of constituent elements that are placed before and after ‘and/or’. Throughout the present specification, the same constituent elements are given the same reference number.

Terms used in the present specification are for describing the embodiments and are not intended to limit the present disclosure. In the present specification, singular forms also include plural forms unless specifically stated otherwise in a phrase. The terms “comprise” and/or “comprising” used in the specification should be construed to mean “including a constituent element, a step, an operation, or an element is mentioned, without excluding the presence or addition of one or more other constituent elements, steps, operations, or elements, respectively.”

The present disclosure relates to a gate-all-around field effect transistor (GAAFET) including trench inner spacers (TISs) and a method for manufacturing the same.

One embodiment of the present disclosure relates to a GAAFET including TISs positioned inside two or more trenches formed on a substrate or a punch through stopper (PTS).

During a process of etching a substrate or PTS to form a source region/a drain region during a general GAAFET manufacturing process, a phenomenon in which the substrate or PTS is unintentionally over-etched frequently occurs due to a process variation or the like. The recess depth of the over-etched source region/drain region may be referred to as ‘T_{SD}’. As the T_{SD} becomes deeper, a phenomenon in which impurities in the source region/drain region diffuse to the bottom of the channels occurs more seriously, which even causes the occurrence of leakage current.

However, since the GAAFET provided by the present disclosure includes TISs having an L-shaped cross section, the GAAFET may solve a problem of the diffusion of impurities or the occurrence of leakage current. As the results of performing a simulation experiment according to the degree of diffusion of impurities according to the depth of T_{SD} in a GAAFET device including TISs with an ‘L’-shaped structure, which will be described below, the present inventors could confirm that, even if the T_{SD} becomes deep, impurities in the source region/drain region can be suppressed from being diffused to the bottom of the channels, thereby making it possible to suppress or minimize the generation of leakage current, and the TISs can be positioned below the source region/drain region to act as an insulator, thereby making it possible to provide an excellent heat release effect.

Describing the structure of the GAAFET according to the present disclosure from the bottom thereof, first, the GAAFET includes a substrate or a PTS located on the top of the substrate, and includes a source region/a drain region formed to be spaced apart from each other on the top of the substrate or PTS, a series of gate stacks vertically stacked therebetween, and a series of channels located below the respective gate stacks and extending between the source region/drain region.

The present disclosure is characterized in that trenches are formed in regions where inner spacers located between a lowermost gate stack and a source region/a drain region are located (stacked) on the top surface of the substrate or the PTS, and the spacers are formed to extend from the inner spacers to the insides of the trenches, and in the present disclosure, spacers particularly located inside the trenches are referred to as “trench inner spacers (TISs)”.

In the present disclosure, one of the trenches formed on the substrate or PTS may be formed in a region corresponding to the inner spacer located between the source region and the lowermost gate stack, and the other one of the trenches may be formed in a region corresponding to the inner spacer located between the drain region and the lowermost gate stack. In the present specification, for convenience, the trenches are referred to as a ‘first trench’ and a ‘second trench’, respectively, but the expressions such as first and second do not limit the manufacturing order, location, or the like. The following description of the trenches may be applied to either or both of the first trench and the second trench.

In the present disclosure, additional trenches may be formed on the substrate or the PTS as needed in addition to the regions where the inner spacers are located.

In the present disclosure, the trenches may have an ‘L’-shaped cross-section as a structure including first regions formed to extend in a longitudinal direction vertically below the substrate or PTS, and second regions which are located below the first regions and of which a cross section is formed to extend in a direction orthogonal to the vertical longitudinal direction.

Further, in the present disclosure, curved surface portions may be included in partial regions, particularly the second regions, of the trenches.

In the present disclosure, the widths of the trenches may be the same as or different from the width of a spacer, for example, an outer spacer or an inner spacer.

Further, in the present disclosure, the separation distance between the first trench and the second trench may be the same as or different from the widths of the gate stacks, and, for example, may be wider than the widths of the gate stacks.

Further, in the present disclosure, Si epitaxial layers may be selectively positioned on the inner surface of the trenches, and TISs may be positioned on the Si epitaxial layers.

In the present disclosure, a spacer may be positioned inside the trenches and may be connected to the bottom of the inner spacers. In the present specification, although, for convenience, a spacer positioned inside the first trench has been referred to as a ‘first trench inner spacer’ or a ‘first TIS’, and a spacer positioned inside the second trench has been referred to as a ‘second trench inner spacer’ or a ‘second TIS’, the expressions such as first and second do not limit the manufacturing order, location, or the like. The description of the TISs described below may be applied to either or both of the first TIS and the second TIS.

Hereinafter, various structures of the GAAFET according to the present disclosure will be described in more detail with reference to the drawings. At this time, ZX rectangular coordinates are indicated on the drawing of the semiconductor device structure in order to provide a spatial context.

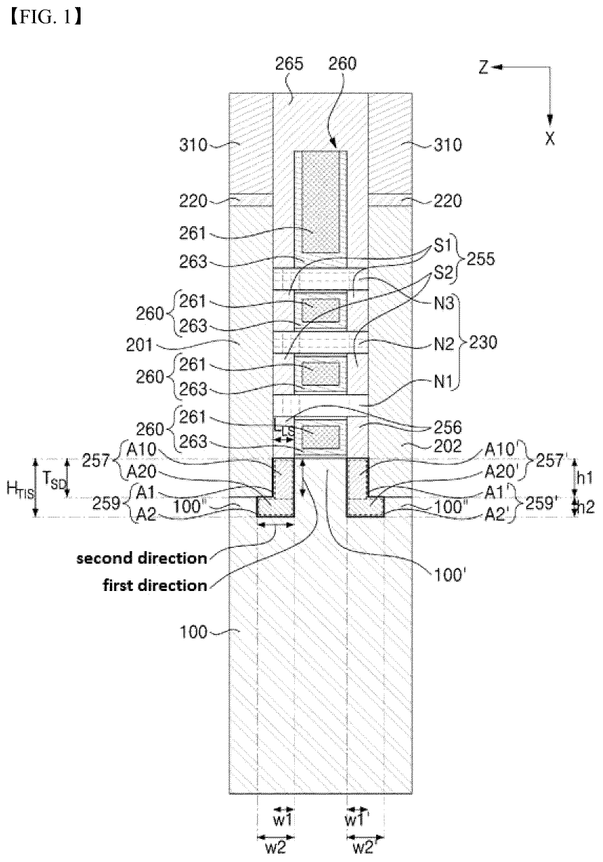

FIG. 1 is a cross-sectional view showing a GAAFET according to a first embodiment of the present disclosure. Describing the structure of the GAAFET according to the present disclosure from the bottom thereof, the GAAFET according to the present disclosure includes a substrate 100 on which two trenches 259 and 259′ positioned to be spaced apart from the bottom by a predetermined distance are formed, source region 201/drain region 202 formed to be spaced apart from each other on the top of the substrate 100, a series of gate stacks 260 between the source region 201/drain region 202, and a series of channels N1, N2, N3, and 230 extending below the gate stacks 260 between the source region 201 and the drain region 202.

Further, the GAAFET according to the present disclosure includes an outer spacer 265 formed on the top and side surfaces of the uppermost gate stack 260, inner spacers S1, S2, 255, and 256 connected to the outer spacer 265 and formed between the source region 201/drain region 202 and the gate stacks 260, and TISs 257 and 257′ located inside the trenches 259 and 259′ and vertically connected to the lowermost inner spacer 256.

First, the substrate 100 is not particularly limited in kind in the present disclosure, and may be a substrate 100 typically used in this field. Representatively, the substrate 100 may be Si, SiGe, Ge, Sn (tin), or Group 3-5 compounds on which a top-down process can be performed. At this time, the Group 3-5 compounds may be, for example, aluminum phosphide (AlP), gallium phosphide (GaP), indium phosphide (InP), aluminum arsenide (AlAs), gallium arsenide (GaAs), indium arsenide (InAs), aluminum antimonide (AlSb), gallium antimonide (GaSb), or indium antimonide (InSb).

The substrate 100 may rarely have doped impurities, or may be doped with one or more n-type impurities selected from P, As, and Sb; or one or more p-type impurities selected from B, BF₂, A1, and Ga. The impurities introduced into the substrate 100 may vary depending on the device type (NMOS or PMOS), and may be p-type in case of NMOS or n-type in case of PMOS.

A region of the substrate 100′ between the two trenches 259 and 259′ in the substrate 100 may have the same thickness as other region 100″, for example, the region 100″ positioned on the bottom of the source region 201/drain region 202, but it may have a thickness different from that. In detail, the region of the substrate 100′ between the first trench 259 and the second trench 259′ is thicker than the substrate 100″ positioned on the bottom of the source region 201/drain region 202 so that it is formed to protrude.

In the substrate 100, a substrate thickness difference h1 between the region 100′ between the two trenches 259 and 259′ and another region 100″ may be a difference T_{SD} according to an over-etched S/D recess depth. The quantitative numerical value range of the thickness difference is not particularly limited, but may be, for example, 0 to 200 nm, 0 to 100 nm, 0 to 50 nm, 0 to 30 nm, 0 to 20 nm, more than 0 nm and not more than 20 nm, or more than 0 nm and not more than 10 nm.

Meanwhile, the first trench 259 and the second trench 259′ may be respectively formed in two regions of the top surface of the substrate 100 where the lowermost inner spacer 256 is located. The TISs 257 and 257′ formed to extend from the inner spacers 255 and 256 may be positioned inside such trenches 259 and 259′.

The trenches 259 and 259′ may include first regions A1 and A1′ of which the cross sections are formed to extend in a first direction, which is a longitudinal direction vertically below the substrate 100, and second regions A2 and A2′ which are located below the first regions A1 and A1′, and of which the cross sections are formed to extend in a second direction orthogonal to the first direction. Here, the first direction may be an X-axis direction, and the second direction may be a Z-axis direction, but the directions are not limited thereto.

The widths w2 and w2′ of the second regions A2 and A2′ of the trenches 259 and 259′ may be equal to or wider than the widths w1 and w1′ of the first regions A1 and A1′. However, as shown in FIG. 1, the widths w2 and w2′ of the second regions A2 and A2′ may be preferably wider than the widths w1 and w1′ of the first regions A1 and A1′ so that the trenches 259 and 259′ may have a groove structure having an ‘L’-shaped cross-section.

Although not shown in the drawings, the second regions A2 and A2′ of the trenches 259 and 259′ may include curved surface portions, and for example, may include curved surface portions at corner portions thereof.

The width of the first regions A1 and A1′ in the trenches 259 and 259′, that is, the range of the Z-axis lateral lengths w1 and w1′ is not particularly limited, but may be, for example, more than 0 nm and not more than 100 nm, 1 to 50 nm, 1 to 30 nm, 1 to 20 nm, 1 to 10 nm, 2 to 9 nm, or 3 to 8 nm.

Further, the range of the widths w2 and w2′ of the second regions A2 and A2′ in the trenches 259 and 259′ is not particularly limited, but may be, for example, more than 0 nm and not more than 200 nm, 2 to 100 nm, 2 to 60 nm, 2 to 40 nm, 2 to 20 nm, 4 to 18 nm, or 6 to 16 nm.

The thickness of the first regions A1 and A1′ in the trenches 259 and 259′, that is, the range of the X-axis vertical length h1 is not particularly limited, but may be, for example, 0 to 200 nm, 0 to 100 nm, or 0 to 50 nm, 0 to 30 nm, 0 to 20 nm, more than 0 nm and not more than 20 nm, or more than 0 nm and not more than 10 nm.

Further, the range of the thickness h2 of the second regions A2 and A2′ in the trenches 259 and 259′ is also not particularly limited, but may be, for example, more than 0 nm and not more than 100 nm, 1 to 50 nm, 1 to 30 nm, 1 to 20 nm, 1 to 10 nm, 2 to 9 nm, or 3 to 8 nm.

In the present disclosure, the width or thickness of each region in the two trenches 259 and 259′ may be the same as or different from each other.

In the present disclosure, a series of gate stacks 260 are positioned on the substrate 100. Each gate stack 260 may be a replacement metal gate. The replacement metal gate includes a gate electrode 261 and a gate dielectric 263 (i.e., a gate dielectric layer or a stack of gate dielectric layers) such as a high-k gate oxide film and an interfacial layer. The gate stacks 260 have a gate-all-around (GAA) structure surrounding the circumference of the regions of the channels 230.

The gate electrode 261 includes a work function metal such as W, A1, Cr, or Ni, and a metal barrier of Ti, TiN, or A1 may be formed if necessary. The gate dielectric 263 may be SiO₂, A1₂O₃, HfO₂, ZrO₂, Si₃N₄, perovskite oxide, or the like. According to one embodiment of the present disclosure, the gate stacks 260 may have a structure in which a gate dielectric/a metal barrier/a work function metal are sequentially stacked.

The channels N1, N2, N3, and 230 may be formed of one or more selected from GaN, Si, Ge, SiGe, GaAS, W, Co, Pt, ZnO, and In₂O₃.

The channels 230 may be a plurality of nanosheet channels. In addition to such a structure, they may be in the form of a known nanowire, nanofiber, nanorod, or nanoribbon, and may be made of a P-type or N-type semiconductor material. The number of layers of the channels 230 is not limited to three, but may be as small as one layer (each layer), and in some embodiments, each channel layer is formed of 2 to 10 layers. The driving current of the GAAFET device may be adjusted by adjusting the number of stacked layers.

In the case of the structure of a nanosheet GAAFET, the channels 230 may be active nanosheet channel layers N1, N2, and N3, and although not shown, sacrificial nanosheet layers are formed between these active nanosheet channel layers. The sacrificial nanosheet layers may be formed of a sacrificial semiconductor material such as Si or SiGe having a Ge concentration different from that of a SiGe material forming the active nanosheet channel layers. However, at this time, the lowermost layer N3 of the active nanosheet channel layers may contain Si. Preferably, the active nanosheet channel layer/sacrificial nanosheet layer have a structure in which Si/SiGe are stacked, and at this time, the sacrificial nanosheet layer is located in a layer close to the substrate 100, and a material thereof may be SiGe.

The source region 201/drain region 202 are formed by epitaxially growing a semiconductor material (e.g., epitaxial Si material or SiGe material) on the exposed sidewall surfaces of the channels N1, N2, N3, and 230 and the exposed top surface of the substrate 100. Specifically, the source region 201/drain region 202 are grown vertically (in the Z-axis direction) and laterally (in the Y-axis direction) on the substrate 100 and along the side surfaces of the channels 230 and formed to protrude.

A silicide 220 and a contact metal layer 310 are formed on the top of the source region 201/drain region 202.

The silicide 220 has a wrap-around-contact structure surrounding the source region 201/drain region 202.

The silicide 220 may preferably include a metal silicide material, may be used by combining metal commonly used for a semiconductor and Si, and may be, for example, a silicide material including Ni, Co, W, Ta, Ti, Pt, Er, Mo, Pd, or alloys thereof. More specifically, the metal silicide material may include NiSi₂, CoSi₂, WSi₂, TaSi₂, TiSi₂, PTIS₂, ErSi₂, MoSi₂, PdSi₂, or combinations thereof, but is not particularly limited in the present disclosure. In addition, the silicide 220 may a single layer or multiple layers containing the above material.

Further, a contact metal layer 310 filled with a metal material such as Co, W, or Ru is formed in order to electrically connect the source region 201/drain region 202.

A GAAFET of such a structure includes a plurality of spacers for various purposes such as insulation between respective layers.

Specifically, an outer spacer 265 is included on the uppermost channel layer N3 and on both surfaces of the uppermost gate stack 260. A series of first inner spacers S1, S2, and 255 are formed between two channel layers formed to be vertically neighboring to each other and between the source region 201/drain region 202 and the gate stacks 260. Second inner spacers 256 are formed on the bottom of the lowermost channel N1 and between the source region 201/drain region 202 and the lowermost gate stack 260.

The outer spacer 265 and the inner spacers 255 and 256 may include an insulating material such as SiO₂, A1₂O₃, HfO₂, ZrO₂, Si₃N₄, or perovskite oxide. Materials of the outer spacer 265 and the inner spacers 255 and 256 may be the same as or different from each other.

In the present disclosure, the TISs 257 and 257′ connected to the bottom of the second inner spacers 256 and located inside the trenches 259 and 259′ may be made of a material that is the same as or different from the inner spacers 255 and 256, and may include the above-mentioned insulating material.

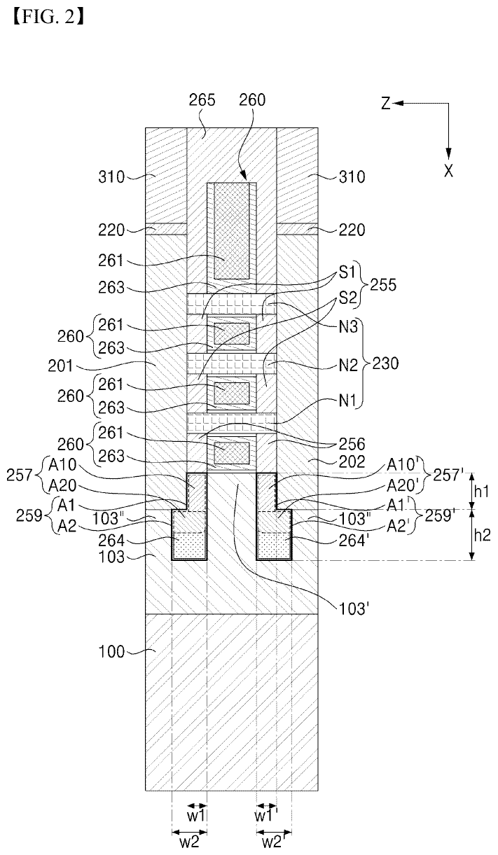

The specific shape of the TISs 257 and 257′ is not particularly limited, but first parts A10 and A10′ filling at least a portion of the first regions A1 and A1′ of the trenches 259 and 259′, and second parts A20 and A20′ filling at least a portion of the second regions A2 and A2′ may be included. At this time, the first parts A10 and A10′ may have a shape corresponding to the first regions A1 and A1′ by filling the entirety of the first regions A1 and A1′, and the second parts A20 and A20′ may also have a shape that fills the entirety of the second regions A2 and A2′, but in a realistic process, the second parts A20 and A20′ may have a shape that fills a portion of the top of the second regions A2 and A2′, and remaining parts 264 and 264′, which are unetched sacrificial layers, may be present in the remaining portions of the second regions A2 and A2′. The remaining parts 264 and 264′ are described in detail with reference to FIG. 2 below.

One end surfaces of the first parts A10 and A10′ and one end surfaces of the second parts A20 and A20′ of the TISs 257 and 257′ may each be in contact with one surface of the source region 201/drain region 202.

In addition, the TISs 257 and 257′ may satisfy Equation 1 below.

$${H}_{TIS} = {T}_{SD} + {L}_{IS} \qquad [ Equation 1 ]$$

where T_{HIS}, as a height (or thickness) of the TISs 257 and 257′, is a vertical length of the TISs with respect to the TIS sidewalls in contact with the source region/drain region, T_{SD} is an over-etched source region/drain region recess depth, and L_{IS} is a lateral length of the second inner spacer, and is equal to a vertical length h2 from the lowermost point in the vertical direction on the TIS sidewalls in contact with the source region/drain region to the top surface of the substrate located on the bottom of the source region/drain region.

T_{SD} may be, for example, 0 to 200 nm, 0 to 100 nm, 0 to 50 nm, 0 to 30 nm, 0 to 20 nm, more than 0 nm and not more than 20 nm, or more than 0 nm and not more than 10 nm, but is not limited thereto.

Further, L_{IS} may be, for example, more than 0 nm and not more than 100 nm, 1 to 50 nm, 1 to 30 nm, 1 to 20 nm, 1 to 10 nm, 2 to 9 nm, or 3 to 8 nm, but is not limited thereto.

As a result, H_{TIS} may be more than 0 nm and not more than 300 nm, more than 0 nm and not more than 200 nm, more than 0 nm and not more than 100 nm, 1 to 80 nm, 1 to 70 nm, 1 to 60 nm, 1 to 50 nm, 1 to 40 nm, 1 to 30 nm, 1 to 20 nm, 1 to 10 nm, or 2 to 10 nm, but is not limited thereto.

Further, the TISs 257 and 257′ may also satisfy Equation 2 below.

$${W}_{TIS \_ BOTTOM} = m \times {W}_{TIS \_ TOP} \qquad [ Equation 2 ]$$

where W_{TIS_TOP} is a width length of the first parts A10 and A10′ of the TISs 257 and 257′, W_{TIS_BOTTOM} is a width of the second parts A20 and A20′ of the TISs 257 and 257′, that is, a lateral length in the Z-axis direction, and m is a rational number more than 1 and not more than 3, and may be preferably a rational number of 1.1 to 3.

Preferably, W_{TIS_TOP} may be equal to the width length w1 of the first regions A1 and A1′, and W_{TIS_BOTTOM} may be equal to the width length w2 of the second regions A2 and A2′.

In Equation 2 above, W_{TIS} T_{OP} may be, for example, more than 0 nm and not more than 100 nm, 1 to 50 nm, 1 to 30 nm, 1 to 20 nm, 1 to 10 nm, 2 to 9 nm, or 3 to 8 nm, but is not limited thereto.

Further, W_{TIS_BOTTOM} may be, for example, more than 0.1 nm and not more than 300 nm, 1 to 150 nm, 1 to 90 nm, 1 to 60 nm, or 2 to 45 nm, but is not limited thereto.

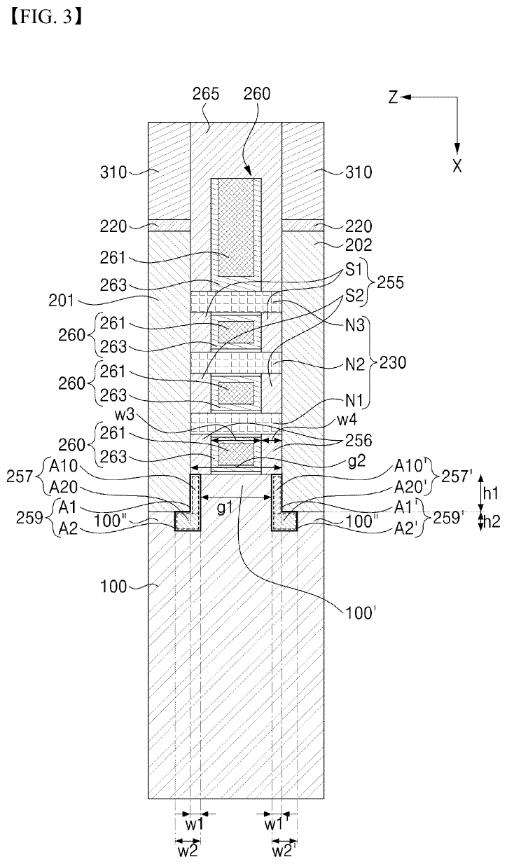

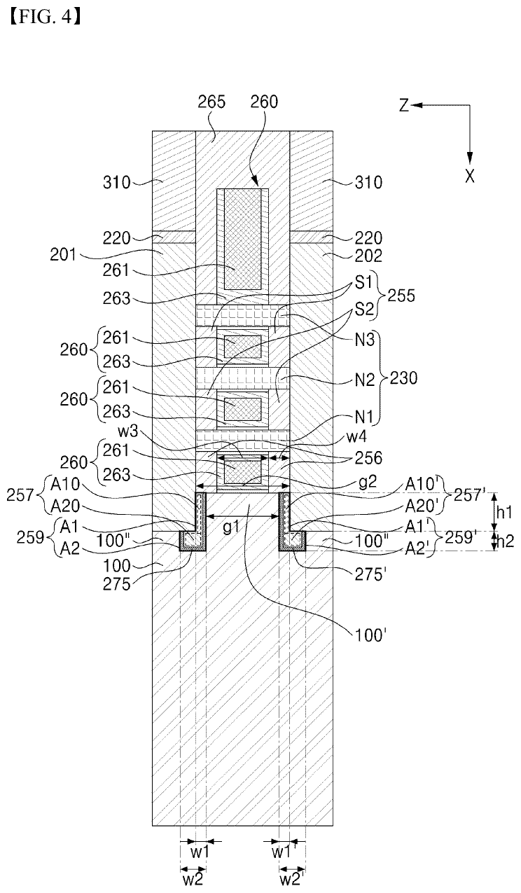

The lateral length in the Z-axis direction of the region of the substrate 100′ between the first trench 259 and the second trench 259′ means a separation distance between the first TIS 257 and the second TIS 257′. At this time, the separation distance may be the same as the width of the lowermost gate stack 260 as shown in FIG. 1, but may be different from the width of the lowermost gate stack 260 as shown in FIGS. 3 and 4.

FIG. 2 is a cross-sectional view showing a GAAFET according to a second embodiment of the present disclosure, in which a PTS 103 is included on a substrate 100, two trenches 259 and 259′ positioned to be spaced apart from each other by a predetermined distance are formed on the PTS, and the TISs 257 and 257′ are positioned inside the trenches 259 and 259′.

In order to effectively prevent leakage current under the channels 230, the PTS 103 is formed by implanting impurities of a type opposite to those of the source region 201/drain region 202 at a high concentration into a predetermined region under the channels and then performing heat treatment. Through the formation of the PTS 103, leakage current generated in the GAAFET device can be effectively suppressed.

Although the PTS 103 is not shown in the drawings other than FIG. 2, the present disclosure also includes all structures in which the above-mentioned trenches 259 and 259′ and the TISs 257 and 257′ positioned inside the trenches 259 and 259′ are formed on the PTS 103 also in the drawings other than FIG. 2.

The TISs 257 and 257′ including the first parts A10 and A10′ and the second parts A20 and A20′ filling at least a portion of the regions are positioned inside the first regions A1 and A1′ and the second regions A2 and A2′ of the trenches 259 and 259′ formed on the PTS 103. The first parts A10 and A10′ of the TISs 257 and 257′ may fill the entirety of the first regions A1 and A1′ of the trenches 259 and 259′ and have a shape corresponding to the regions. The second parts A20 and A20′ may also fill the entirety of the second regions A2 and A2′ and have a shape corresponding to the regions, but in terms of a realistic process, the remaining parts 264 and 264′, which are unetched sacrificial layers, may remain in the lower portions of the second regions A2 and A2′, and the second parts A20 and A20′ of the TISs 257 and 257′ may be positioned on the remaining parts 264 and 264′.

At this time, since the remaining parts 264 and 264′ are a portion of the sacrificial layers, the remaining parts 264 and 264′ may contain Si, Ge, or a combination thereof, but the present disclosure is not limited thereto.

As shown in FIG. 2, when the remaining parts 264 and 264′ are present in the lower portions of the second regions A2 and A2′, the top surfaces of the remaining parts 264 and 264′ and the bottom surfaces of the TISs 257 and 257′ may have a shape in which at least a portion of the top surfaces of the remaining parts 264 and 264′ is in contact with at least a portion of the bottom surfaces of the TISs 257 and 257′. The specific shapes of the upper surfaces of the remaining parts 264 and 264′ and the bottom surfaces of the TISs 257 and 257′ are not particularly limited, and examples thereof may include various shapes such as a cross section, a straight line such as an oblique line, or a curve such as a meandering shape without limitation.

The TISs 257 and 257′ of the present disclosure have a structure that may not be found in conventional GAAFET devices, and provide the above-mentioned advantages regardless of whether or not the remaining parts 264 and 264′ are present below the TISs 257 and 257′. Although the remaining parts are not shown in the remaining drawings except for FIG. 2, the present disclosure includes all structures in which the remaining parts 264 and 264′ are located in the lower portions inside the trenches 259 and 259′ in the remaining drawings as well.

FIG. 3 is a cross-sectional view showing a GAAFET according to a third embodiment of the present disclosure. In the GAAFET of the structure presented in FIG. 3, the two trenches may be spaced apart from each other by a distance wider than the widths of the gate stacks, and thus the two TISs located inside the two trenches may also have a wide separation distance, which makes it possible to minimize the occurrence of device defects due to misalignment between the device and the TISs. More specifically, the GAAFET device can be electrically connected by precisely matching interlayer patterns. Even if alignment, which is an operation of matching the interlayer patterns through repetitive lithography processes, is performed, it is not easy to align the position of these patterns. Particularly, since the TISs in the present disclosure has a narrow and long pattern, there is a high probability of misalignment. Accordingly, as shown in FIG. 3, when the distance between the TISs 257 and 257′ is increased while the lateral length of the gate stacks 260 of the device is maintained, position alignment is facilitated, which is advantageous in securing an alignment margin of the interlayer patterns.

As a specific structure of the GAAFET according to the present disclosure shown in FIG. 3, a first trench 259 and a second trench 259′ are formed on the substrate 100, and at this time, the GAAFET according to the present disclosure has a structure in which a separation distance g1 between the two trenches 259 and 259′ is wider than the width w3 of the gate stacks, but is smaller than a length g2 obtained by summing up the width w3 of the lowermost gate stack 260 and a width w4 (Lis) of the second inner spacer 256. Accordingly, the first TIS 257 and the second TIS 257′ located in the two trenches 259 and 259′ are also positioned to be spaced apart from each other by a distance wider than the width w3 of the gate stacks.

Specifically, the separation distance g1 may satisfy Equation 3 below.

$$g 1 = w 3 + 2 \times ( n \times w 4 ) \qquad [ Equation 3 ]$$

where n is a rational number of more than 0 and less than 1, and may preferably be a rational number of 0.1 to 0.9, or 0.2 to 0.9.

An increase in the numerical value of n means that the separation distance between the two trenches 259 and 259′ increases, which means that the separation distance between the first and second TISs 257 and 257′ also increases. At this time, if the separation distance becomes too long, the widths of the upper regions of the first TIS 257 and the second TIS 257′ become narrow so that misalignment may rather occur. Therefore, it is preferable to extend the separation distance within the above range.

The g1 is a separation distance between the first trench 259 and the second trench 259′, and may be, for example, more than 0 nm and not more than 400 nm, but is not limited thereto.

The w3 is the width of the lowermost gate stack 260, and may be, for example, more than 0 nm and not more than 200 nm, but is not limited thereto.

The w4 is the width of the second inner spacer, and may be, for example, more than 0 nm and not more than 100 nm, 1 to 50 nm, 1 to 30 nm, 1 to 20 nm, 1 to 10 nm, 2 to 9 nm, or 3 to 8 nm, but is not limited thereto.

Meanwhile, regarding the shapes of the trenches 259 and 259′, the trenches 259 and 259′ may include first regions A1 and A1′ formed to extend in a first direction from the substrate 100, and second regions A2 and A2′ which are positioned under the first regions A1 and A1′ and of which cross sections are formed to extend in a second direction orthogonal to the first direction. At this time, the widths w2 and w2′ of the second regions A2 and A2′ may be wider than the widths w1 and w1′ of the first regions A1 and A1′, and the widths w1 and w1′ of the first regions A1 and A1′ may be narrower than the width of the inner spacers 256.

More specifically, the widths w1 and w1′ of the first regions A1 and A1′ may be, for example, more than 0 nm and not more than 100 nm, 1 to 50 nm, 1 to 30 nm, 1 to 20 nm, 1 to 10 nm, 2 to 9 nm, or 3 to 8 nm, but are not limited thereto.

The widths w2 and w2′ of the second regions A2 and A2′ may be, for example, more than 0 nm and not more than 200 nm, 2 to 100 nm, 2 to 60 nm, 2 to 40 nm, 2 to 20 nm, 4 to 18 nm, or 6 to 16 nm, but are not limited thereto.

The TISs 257 and 257′ including the first parts A10 and A10′ filling at least a portion of the first regions A1 and A1′ and the second parts A20 and A20′ filling at least a portion of the second regions A1 and A1′ are located inside the trenches 259 and 259′.

The other description of the trenches 259 and 259′ and the TISs 257 and 257′, or the description of the rest components except for the trenches and TISs of the GAAFET are redundant with those described above so that the description thereof is omitted hereinafter.

FIG. 4 is a cross-sectional view showing a GAAFET according to a fourth embodiment of the present disclosure, and the structure presented in FIG. 4 is related to a patterning process for TIS formation. The trench pattern is formed to be narrow and long, and a trench having a high aspect ratio may be a factor in lowering the process yield. Accordingly, after forming wide trenches having a width wider than that of the inner spacers, the width of the TISs positioned inside the trenches may be adjusted by selectively forming Si epitaxial layers on the inner surface of the trenches.

In the GAAFET according to the present disclosure shown in FIG. 4, two trenches 259 and 259′ are formed on a substrate 100, and the trenches 259 and 259′ include first regions A1 and A1′ of which cross sections are formed to extend in a first direction and second regions A2 and A2′ positioned below the first regions A1 and A1′ and of which cross sections are formed to extend in a second direction, wherein Si epitaxial layers 275 and 275′ are positioned on the entirety or a portion of the inner surfaces of the trenches 259 and 259′.

In the trenches 259 and 259′, TISs 257 and 257′ may be positioned on the Si epitaxial layers 275 and 275′. At this time, the width of the TISs 257 and 257′ can be precisely adjusted by adjusting the thickness of the Si epitaxial layers 275 and 275′.

The thickness of the Si epitaxial layers 275 and 275′ is not particularly limited, but may be, for example, more than 0 nm and not more than 100 nm, more than 0 nm and not more than 80 nm, 0.1 to 50 nm, 1 to 30 nm, or 2 to 10 nm, but is not limited thereto.

In FIG. 4, other than the previously described parts, the description of the thickness of the trenches 259 and 259′, or the TISs 257 and 257′, or the description of the rest components except for the trenches and TISs of the GAAFET are redundant with those described above so that the description thereof is omitted hereinafter.

However, in FIG. 4, only the structure in which the two trenches 259 and 259′ are formed to be spaced apart from each other by a distance wider than the widths of the gate stacks 260 is shown, but the present disclosure may also include a structure in which the Si epitaxial layers 275 and 275′ are positioned on the inner surfaces of the trenches 259 and 259′ in a structure in which the two trenches 259 and 259′ are formed to be spaced apart from each other by the same distance as the widths of the gate stacks 260 as shown in FIG. 1.

Another embodiment of the present disclosure relates to a method for manufacturing a GAAFET including the TISs, wherein the GAAFET device having the above-described structure to adjust the shape and the distance of the TISs, and the GAAFET device can be manufactured through modification in the patterning step.

Hereinafter, the method for manufacturing a GAAFET device having TISs according to the present disclosure will be described.

At this time, the formation of each layer includes a deposition process, a lithography process, and an etching process, and each layer is formed by another appropriate processes in addition to the processes or combinations thereof. Unless otherwise specified, each layer is subjected to a deposition process, followed by a lithography process and an etching process in this order.

The deposition process includes CVD, physical vapor deposition (PVD), atomic layer deposition (ALD), high density plasma chemical vapor deposition (HDPCVD), metal organic chemical vapor deposition (MOCVD), remote plasma chemical vapor deposition (RPCVD), plasma-enhanced chemical vapor deposition (PECVD), low pressure chemical vapor deposition (LPCVD), atomic layer chemical vapor deposition (ALCVD), atmospheric pressure chemical vapor deposition (APCVD), evaporation deposition, plating, other suitable methods, or combinations thereof.

The lithography process may include any one process of electron beam lithography, nanoimprint, ion beam lithography, X-ray lithography, extreme ultraviolet lithography, photolithography (stepper, scanner, contact aligner, etc.), maskless lithography, or randomly scattered nanoparticles, and is not particularly limited in the present disclosure. The photolithography process among them includes resist coating (e.g., spin on coating), soft baking, mask alignment, exposure, post-exposure baking, resist development, rinsing, drying (e.g., hard baking), other suitable processes, or combinations thereof.

The etching process includes a dry etching process, a wet etching process, another etching process, or combinations thereof Δt this time, metals such as Cr, Ni, and A1, or photoresist in addition to insulating films such as SiO₂ and SiNₓ may be used as an etching mask material.

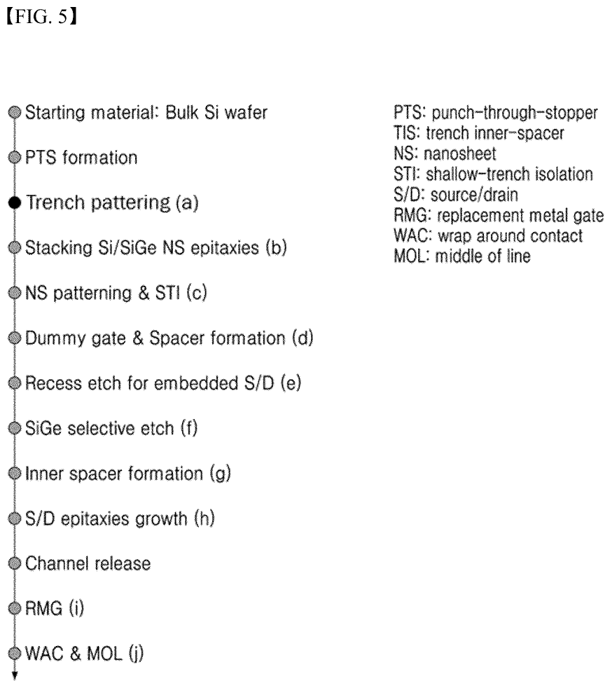

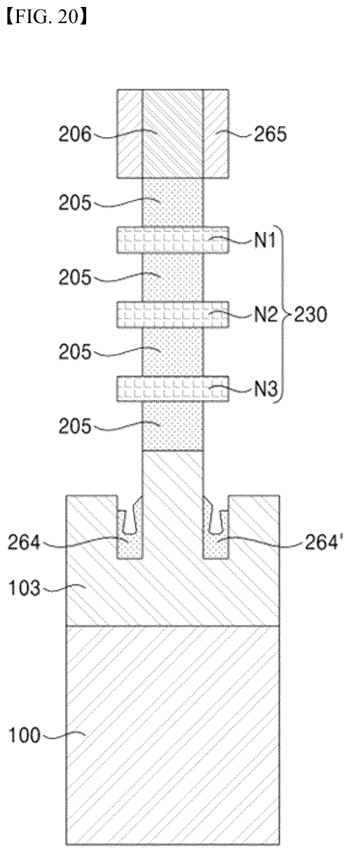

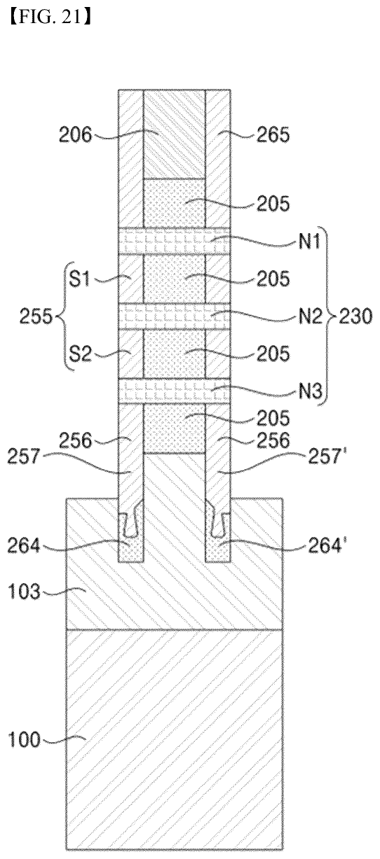

FIGS. 5 to 21 are views showing a method for manufacturing a GAAFET device according to one embodiment of the present disclosure. For understanding, the method for manufacturing a GAAFET device is described by the Z-X cross sectional view of the device.

FIG. 5 is a flowchart for explaining a method for manufacturing a GAAFET device, and the method for manufacturing a GAAFET device is carried out by including steps of:
(a) patterning trenches on the top of one side of a substrate or a punch through stopper (PTS);
(b) forming pluralities of channels and sacrificial layers alternately arranged on the substrate or the punch through stopper (PTS);
(c) forming two trenches positioned to be spaced apart from each other and patterning the channels and sacrificial layers;
(d) forming a dummy gate and an outer spacer;
(e) vertically etching the channels and the sacrificial layers in order to form a source region/a drain region;
(f) selectively etching portions of the sacrificial layers in contact with the channels;
(g) forming inner spacers and TISs;
(h) forming a source region/a drain region by a selective epitaxial growth process;
(i) releasing the channels;
(j) forming a replacement metal gate; and
(k) performing WAC and MOL processes.

Hereinafter, each step will be described with reference to the drawings.

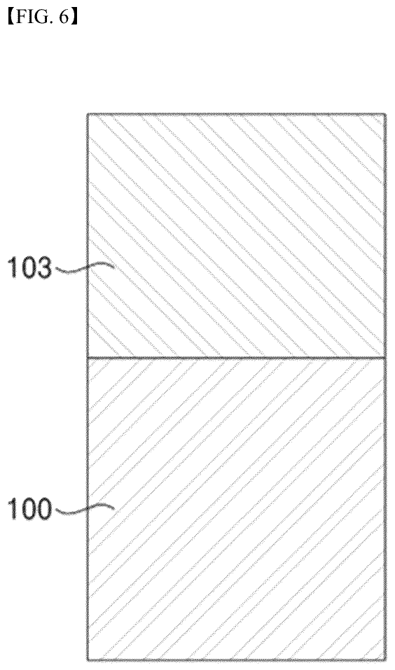

First, prior to performing each of the above-mentioned steps, a step of preparing the substrate 100 or forming the PTS 103 on the substrate may be performed (see FIG. 6).

In order to effectively prevent leakage current under the channels 230, the PTS 103 is formed by implanting impurities of a type opposite to those of the source region 201/drain region 202 at a high concentration into a predetermined region under the channels 230, and then performing heat treatment.

The PTS 103 is formed by performing a heat treatment process after impurity implantation. The processes are applied prior to the selective epitaxial growth process for forming the source region 201/drain region 202, and more preferably, just before a process of forming a shallow trench isolation (STI) region so that the device is not damaged or becomes disadvantageous due to these processes.

This PTS 103 is optional and is shown in the drawing for better understanding, but can be excluded. In that case, each step performed on the PTS described below may be performed on the substrate.

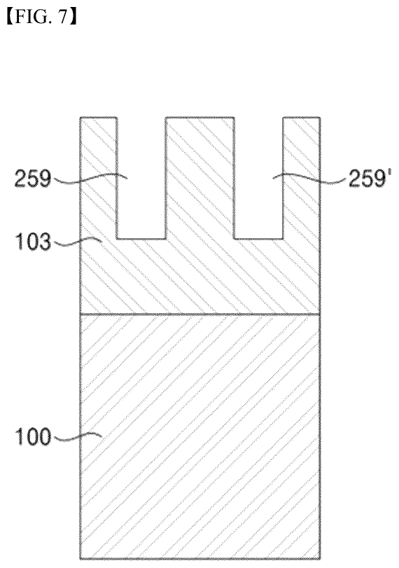

Next, the top of one side of the substrate 100 (when no PTS is formed) or the PTS 103 is etched and patterned to have a first trench 259 and a second trench 259′ (see FIG. 7).

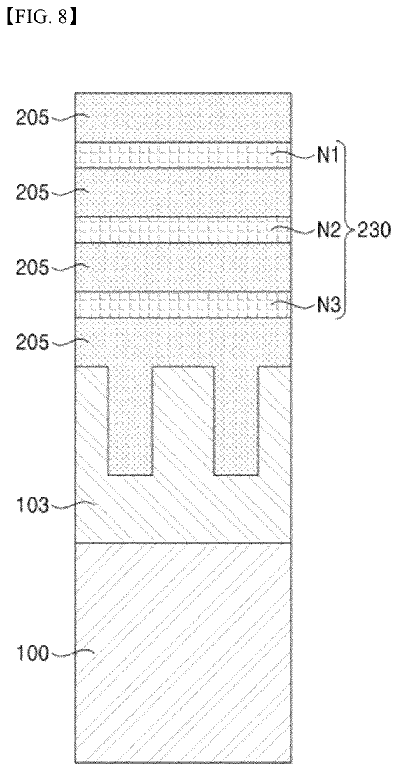

At this time, GAAFETs of various TIS structures may be implemented by adjusting the width and separation distance of the first trench 259 and the second trench 259′. As an example, as shown in FIG. 8, the trenches 259 and 259′ may be patterned wide so as to have a width wider than that of the outer spacer 265 formed on both sides of the uppermost gate stack 260 to be stacked in the future or the inner spacer 256. More specifically, the trenches 259 and 259′ are patterned in an imaginary region that is vertically below from the outer spacer 265 out of the top surface of the substrate 100 or the PTS 103. At this time, the trenches 259 and 259′ may be etched so as to have a width wider than that of the outer spacer 265, and such structure is named “wide trenches” in the present disclosure.

Next, pluralities of channels 230 and sacrificial layers 205 alternately arranged on the substrate 100 or the PTS 103 are formed (FIG. 8).

The channels 230 may be active nanosheet channel layers (Si NS), and the sacrificial layers 205 may be sacrificial nanosheet layers (SiGe NS). The sacrificial nanosheet layers may be formed of a sacrificial semiconductor material such as Si or SiGe having a Ge concentration different from that of an SiGe material forming the active nanosheet channel layers. According to one embodiment, the active nanosheet channel layers are Si, the sacrificial nanosheet layers are SiGe, and the lowermost sacrificial nanosheet layer contains an SiGe material. That is, in the case of FIG. 8, the nanosheet GAAFET is composed of layers of SiGe/Si/SiGe/Si/SiGe/Si/SiGe from the bottom thereof.

Particularly, the sacrificial layer 205 (SiGe NS) located in the lowermost layer is filled up to the insides of the trenches 259 and 259′, which are TIS formation regions, unlike the conventional art, and as shown in FIG. 8, a portion of the sacrificial layer 205 of the lowermost layer shows a T-shaped structure extending in the vertical direction.

As will be described later, even if the sacrificial layers 205 are not sufficiently filled up to the insides of the trenches 259 and 259′ and voids are generated inside the trenches, etching of the trenches 259 and 259′ is performed in a subsequent process of vertically etching the side surfaces of the sacrificial layers 205, and thus TIS formation and defects are not substantially affected.

Next, the channels 230 and the sacrificial layers 205 are patterned, and the STI region 101 is formed (not shown).

Side surfaces of the channels 230 and the sacrificial layers 205 are vertically etched to form nanostructures.

The isolation insulating layer, that is referred to as a shallow trench isolation (STI) region 101, may be formed of a suitable dielectric material selected from low-k dielectrics such as silicon oxide, silicon nitride, silicon oxynitride, fluorine-doped silicate glass (FSG), and carbon-doped oxide, ultra low-k dielectrics such as porous carbon-doped silicon dioxide, polymers such as polyimide, combinations thereof, and the like. If necessary, it may be formed of a silicon oxide material through a thermal oxidation process of the substrate 100.

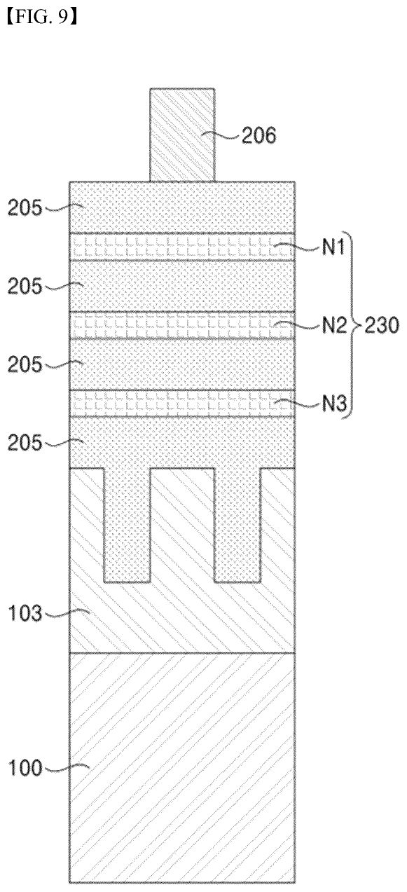

Next, a dummy gate 206 is formed to surround the channels 230 and the sacrificial layers 205 (FIG. 9). The dummy gate 206 may be a polysilicon gate, and is formed through a patterning process after deposition.

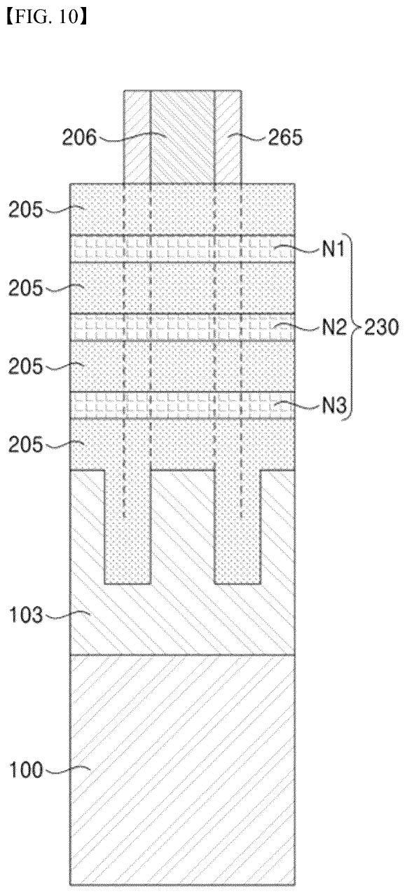

Next, an outer spacer 265 is formed (FIG. 10).

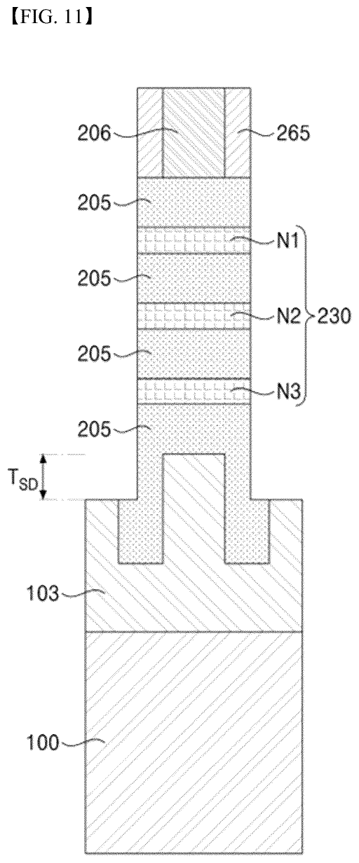

The outer spacer 265 is formed through a patterning process after performing deposition using a material having insulating properties so that the channels 230 and the sacrificial layers 205 are surrounded. As seen from a cross-sectional view taken along line A-A′ in FIG. 11, the outer spacer 265 is formed on the channels 230 and the sacrificial layers 205 in a manner that is spaced a predetermined distance apart vertically from the bottom. At this time, a portion of the lower end of the sacrificial layer 205 in contact with the PTS 103 shows a structure extending in a vertical direction into the PTS 103 like a ‘T’ shape.

FIG. 10 is a view showing the formation of wide trenches by a wide patterning method, wherein in a state that the separation distance g1 between the first trench 259 and the second trench 259′ is maintained to be equal to the width of the dummy gate 206, the first and second trenches 259 and 259′ described above are formed so as to have a width wider than that of the outer spacer 265.

Next, the channels 230 and the sacrificial layers 205 are vertically etched in order to form a source region 201/a drain region 202 (FIG. 11). At this time, during the etching, the channels 230 and the sacrificial layers 205 are vertically etched based on the exposed end surfaces of both sides of the outer spacer 265. However, additional etching may occur as much as T_{SD} in the PTS 103 or the substrate 100 due to variables during the vertical etching process. In that case, since the first and second trenches 259 and 259′ have a wider width than the outer spacer 265, partial regions of the outer cross sections of the first and second trenches 259 and 259′ that do not correspond to the outer spacer 265 may also be etched. Accordingly, in the finally manufactured GAAFET structure, the trenches 259 and 259′ include first regions A1 and A1′ and second regions A2 and A2′ having different widths.

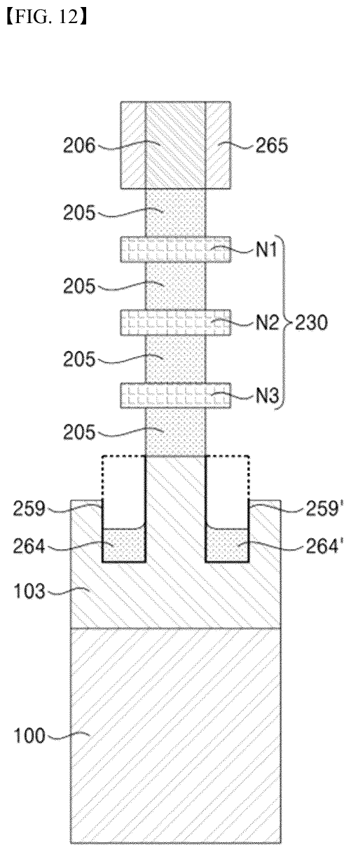

Next, a selective etching process for the sacrificial layers 205 in contact with the channels 230 is performed (FIG. 12).

In the selective etching process, only the sacrificial layers 205 are selectively etched using a difference in etching rate according to a material composition ratio or material difference between the channels 230 and the sacrificial layers 205. In order to remove performance deterioration factors such as surface state density generated on the etching surface during the etching process, a process of removing the grown film through dry etching or wet etching after growing a film by using a thermal oxidation process may be added.

When the sacrificial layers 205 are selectively etched, etching is performed up to the insides of the trenches 259 and 259′. However, when a portion of the sacrificial layer 205 located particularly at the lower end portion of the inner regions of the trenches 259 and 259′ is unetched, the remaining parts 264 and 264′ may remain (e.g., SiGe residue). If necessary, the remaining parts 264 and 264′ may be completely removed through additional etching or selective etching.

After additional etching, wide trenches 259 and 259′ of the substrate 100 or PTS 103 are formed, which provide a substantial space for the formation of the TISs 257 and 257′.

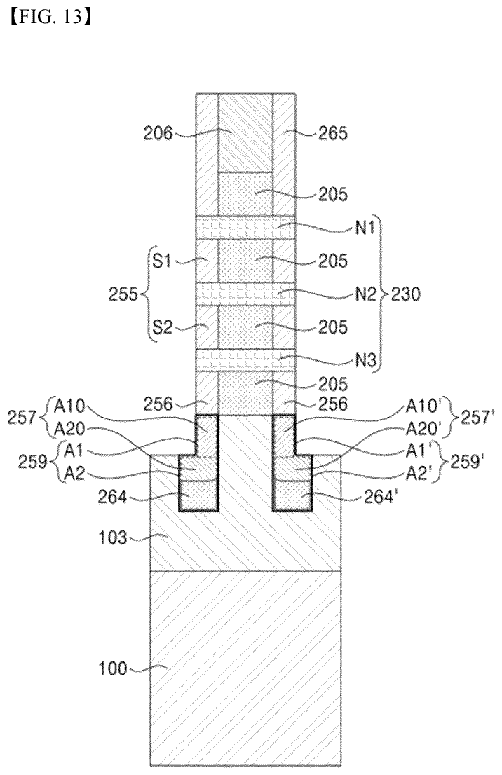

Next, the first and second inner spacers 255 and 256, and the TISs 257 and 257′ connected thereto and extended up to the inner regions of the trenches 259 and 259′ are formed by depositing an insulating material on the regions of the sacrificial layers 205 exposed by the selective etching process (FIG. 13).

However, as described above, portions (264 and 264′) of the unetched sacrificial layers may remain in the lower portion of the trenches 259 and 259′ during the selective etching process of the sacrificial layers 205, in which case the TISs 257 and 257′ may be deposited and formed up to the top of the remaining parts 264 and 264′.

If over-etching occurs during the previous etching process for forming the source region/drain region, as portions of the outer cross sections of the wide trenches 259 and 259′ are etched together, a width difference may occur between the first parts A10 and A10′, which are the upper portions of the TISs 257 and 257′, and the second parts A20 and A20′, which are the lower portions of the TISs 257 and 257′, and a height difference occurs between the PTS region between the two TISs 257 and 257′ and the PTS region where the source region 201/drain region 202 are to be located. However, although not shown in the drawings, when the above-described over-etching does not occur, no height difference is present between the PTS in the two regions.

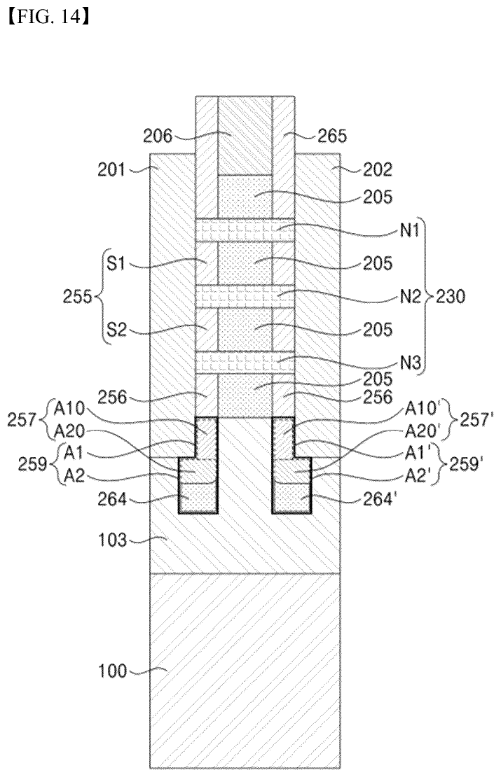

Next, source region 201/drain region 202 are formed by a selective epitaxial growth process (FIG. 14).

Selective epitaxial growth is performed by epitaxially growing a semiconductor material (e.g., epitaxial Si material, silicon carbide (SiC) material, or SiGe material) on the exposed sidewall surfaces of the channels N1, N2, N3, and 230.

For the selective epitaxial growth process, solid phase epitaxy (SPE), vapor phase epitaxy (VPE), and liquid phase epitaxy (LPE) methods may be used. According to one embodiment, an epitaxial layer may be formed by epitaxial growth (e.g., hetero-epitaxy) using a chemical vapor deposition (CVD), reduced pressure chemical vapor deposition (RPCVD), ultrahigh vacuum chemical vapor deposition (UHCVD), or molecular beam epitaxy (MBE) method.

The source region 201/drain region 202 are formed to protrude by being grown vertically (in the Z-axis direction) and laterally (in the Y-axis direction) along the side surfaces of the channels 230 by the selective epitaxial growth process.

Through the selective epitaxial growth process, n-type or p-type impurities are implanted into the source region 201/drain region 202 without a separate ion implantation process.

At this time, the impurity type varies depending on the device type (NMOS or PMOS), and it may be n-type in case of NMOS or p-type in case of PMOS. For example, the source region 201/drain region 202 may be doped with one or more n-type impurities selected from P, As, and Sb; or one or more p-type impurities selected from B, BF₂, A1, and Ga.

If necessary, in order to increase the stress effect of the channels 230, Si, SiGe, Ge, Sn (tin), and Group 3-5 compounds in addition to the impurities may be mixed and used. At this time, the Group 3-5 compounds may be, for example, aluminum phosphide (AlP), gallium phosphide (GaP), indium phosphide (InP), aluminum arsenide (AlAs), gallium arsenide (GaAs), indium arsenide (InAs), aluminum antimonide (AlSb), gallium antimonide (GaSb), or indium antimonide (InSb).

The height of TISs, that is, Hₜᵢₛ, is involved in T_{SD}, as mentioned in Equation 1, and even if the T_{SD} variation occurs, diffusion of the impurities of the source region 201/drain region 202 into the part under the channels 230 is prevented.

Next, the step of releasing the channels is performed.

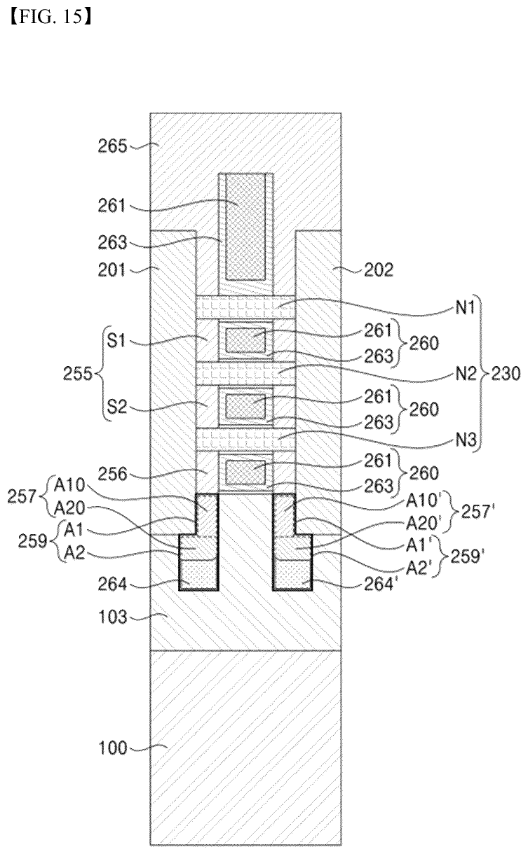

Next, a gate stack 260 is formed by performing a replacement metal gate (RMG) forming process (FIG. 15).

The gate stack 260 is formed by removing the existing dummy gate 206 and depositing a gate electrode 261 and a gate dielectric 263. As shown in FIG. 1, the gate stack 260 has a GAA structure that surrounds a top, a bottom and/or a lateral-side surface of the channel 230, that is, three-dimensionally surrounds the channel 230.

Next, a process of forming silicide 220 on the source region 201/drain region 202 is performed.

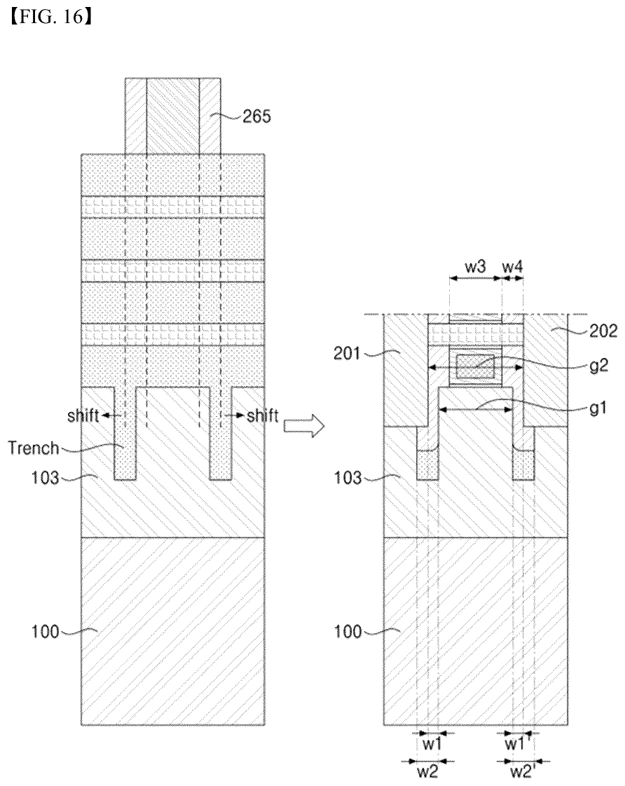

The source region 201/drain region 202 include a silicon or polysilicon material, and silicide is formed by implanting metal ions such as Ni, Co, W, Ta, Ti, Pt, Er, Mo, Pd, or alloys thereof thereinto. As a result, as shown in FIG. 16, the silicide 220 is formed to surround the source region 201/drain region 202, and the contact opening region remains exposed.

Next, the contact metal layer 310 is formed by performing a wrap around contact (WAC) and middle of line (MOL) processes for filling the contact opening region with metal. Filling of the contact metal layer may be performed through a deposition process of a metal material such as Co, W, or Ru.

The GAAFET manufactured through the steps described above may be a GAAFET having TISs of a trench structure with a cross section extending in an outer width direction orthogonal to the length direction, and it is possible to manufacture a GAAFET of another embodiment through a change in a trench patterning process.

Meanwhile, FIG. 16 shows some steps of a GAAFET manufacturing process for forming the trenches and TISs of the structure shown in FIG. 2, and the trench patterning process shown in FIG. 8 can be replaced with the following process. Specifically, a first trench 259 and a second trench 259′ are patterned on the PTS 103, and the trenches 259 and 259′ are patterned so that the two trenches 259 and 259′ are spaced apart from each other by a distance wider than the width of a dummy gate 206 or the gate stacks 260 to be stacked in the future. However, both of the first and second trenches 259 and 259′ may be patterned to have a width that is the same as the width of the outer spacer 265. At this time, the separation distance g1 may be wider than the width w3 of the gate stacks, but may be shorter than the separation distance g2 between the source region/drain region.

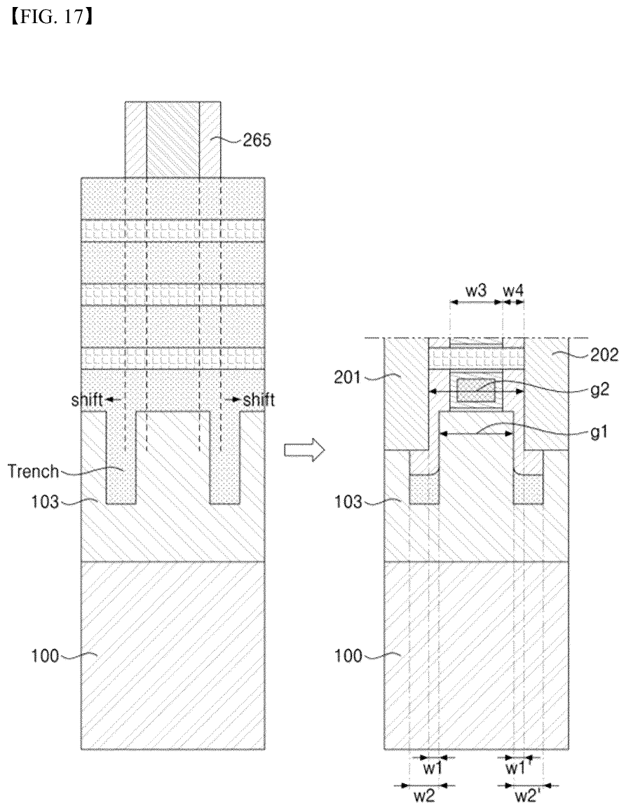

As another example, FIG. 17 shows some steps of a GAAFET manufacturing process for forming the structure of the trenches and TISs shown in FIG. 3, and the trench patterning process shown in FIG. 8 can be replaced with the following process. Specifically, the first trench 259 and the second trench 259′ are patterned on the PTS 103, the two trenches 259 and 259′ are patterned to be spaced apart from each other by a distance wider than the width of a dummy gate 206, or gate stacks 260 that are to be stacked in the future, and both of the first and second trenches 259 and 259′ are patterned to have a width wider than that of the outer spacer 265. The separation distance g1 between the two trenches 259 and 259′ may be wider than the width w3 of the gate stacks, but may be shorter than the separation distance g2 between the source region/drain region.

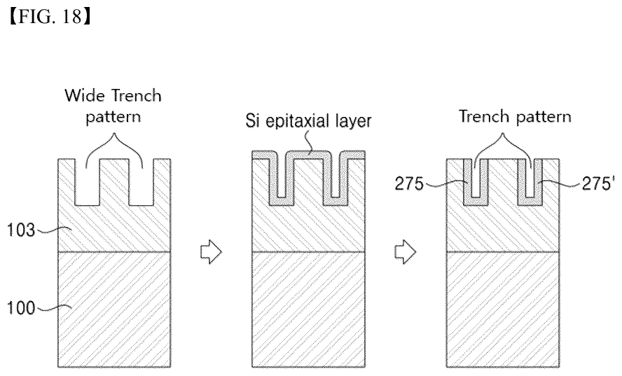

In the present disclosure, after the trench patterning process shown in FIGS. 8, 16, and 17, a process of selectively forming Si epitaxial layers 275 and 275′ having a predetermined thickness on at least a portion of the inner circumferential surfaces of the trenches 259 and 259′ by an epitaxial growth process may be additionally performed (FIG. 18). Here, since it is difficult to proceed with subsequent channel stacking if a material other than Si is deposited, Si epitaxial growth is performed. Since this process is performed at the beginning of the GAAFET manufacturing process, the consistency of patterning can be precisely adjusted so that there is an advantage in that the possibility and completeness of technology application are very high.

Such a process of forming the Si epitaxial layers 275 and 275′ is performed after patterning the trenches 259 and 259′ having a width wider than the outer spacer 265, that is, the wide trenches, so that the width of the TISs 257 and 257′ to be deposited on the insides of the trenches 259 and 259′ may be maintained to be the same as that of the outer spacer 265 or the inner spacers 255 and 256. However, depending on the purpose, the width of the TISs can be sufficiently adjusted to be smaller or larger than the width of the spacers 255, 256 and 265 by adjusting the formation thickness of the Si epitaxial layers 275 and 275′.

All of FIGS. 5 to 17 described above show only an example in which the PTS 103 is stacked on the substrate 100 and then the trenches 259 and 259′ are formed on the PTS 103, but a process of forming the trenches 259 and 259′ on the substrate 100 without the PTS 103 is also included in the present disclosure.

The GAAFET device having the TISs according to the present disclosure as described above has advantages of enabling leakage current to be prevented from occurring under the channels that cannot be controlled by the gate through the TISs and facilitating release of heat from the source region/drain region to the substrate.

Further, as the source region/drain region recesses become deeper, the depth of the trench inner spacers also becomes deeper at the same time so that there is robustness of source region/drain region recess process variables.

Particularly, the trench inner spacers require a trench pattern with a narrow width, and this may be difficult to be realized in an actual process due to a high aspect ratio, but the trench pattern with a narrow width may be easily formed by forming a wide trench pattern in the present disclosure, and thus applying the wide trench pattern to the actual process.

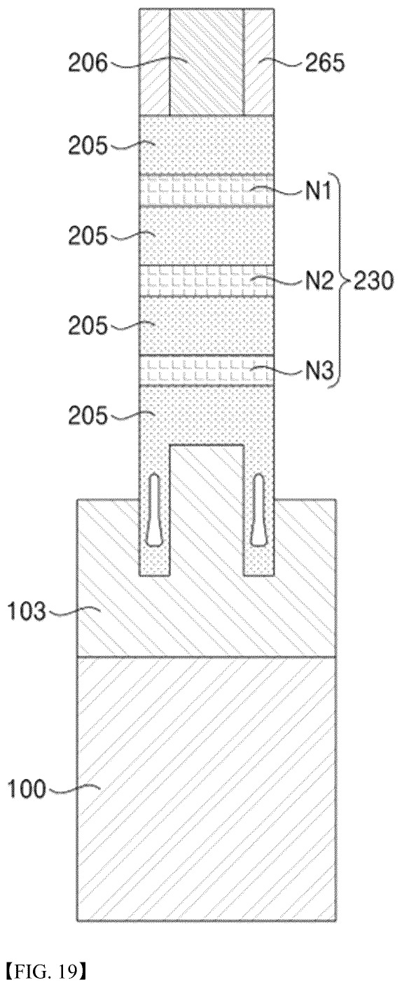

In addition, in the GAAFET device according to the present disclosure, voids may be formed inside the sacrificial layers due to the nature of the trench pattern with a narrow width. During the selective etching process on the side surfaces of the sacrificial layers 205 as shown in FIGS. 19 to 21, etching is performed up to the region where the voids are formed, and then the TISs are formed by filling the voids with the insulating material so that the occurrence of defective GAAFET devices due to the voids can be prevented.

In addition, it is possible to minimize the occurrence of device defects due to misalignment between the trench inner spacers and the device.

Such a technique can be applied to all semiconductor products that utilize three-dimensional GAAFET devices, and it is possible to expect an increase in production yield and a reduction in costs by reduced power consumption due to reduced leakage current, and the robustness of the source region/drain region recess process variables.

In addition, since the trench patterning process for forming the trench inner spacers (TISs) is performed at the beginning of the manufacturing process of the device, the patterning consistency can be precisely controlled so that there is an advantage in that the possibility and completeness of technology application are very high. In addition, since the existing processing processes may be utilized as the other processing processes without any change, the present technique has high applicability.

Although the embodiments of the present disclosure have been described with reference to the accompanying drawings, the present disclosure may be embodied in other specific forms without changing its technical spirit or essential features. Therefore, it should be understood that the embodiments described above are illustrative in all respects and not restrictive.

### DESCRIPTION OF THE REFERENCE NUMERALS

100, 100′, 100″: Substrate
101: STI region
103, 103′, 103″: PTS
201, 202: Source region/drain region
205: Sacrificial layers
206: Dummy gate
220: Silicide
N1, N2, N3, 230: Channels
S1, S2, 255: First inner spacers
256: Second inner spacers
257: First trench inner spacer (TIS)
257′: Second trench inner spacer (TIS)
259: First trench
259′: Second trench
A1: First region of first trench
A1′: First region of second trench
A2: Second region of first trench
A2′: Second region of second trench
A10: First part of first trench inner spacer
A10′: First part of second trench inner spacer
A20: Second part of first trench inner spacer
A20′: Second part of second trench inner spacer
260: Gate stacks
261: Gate electrode
263: Gate dielectric
264: First remaining part
264′: Second remaining part
265: Outer spacer
275: First epitaxial layer
275′: Second epitaxial layer
310: Contact metal layer

### INDUSTRIAL APPLICABILITY

The present disclosure relates to a gate-all-around field effect transistor having trench inner spacers and a method for manufacturing the same.

1. A gate-all-around field effect transistor comprising:
a substrate on which trenches are formed, or a punch through stopper (PTS) which is positioned on the substrate, and on which trenches are formed;
a source region/drain region formed to be spaced apart from each other on the substrate or the punch through stopper (PTS);
a plurality of channels connecting the source region/drain region;
a plurality of gate stacks having a gate-all-around (GAA) structure surrounding at least a portion of the perimeter of the channels;
first inner spacers included between the source region/drain region and the gate stacks;
second inner spacers located on the bottom of a lowermost channel among the plurality of channels and included between the source region/drain region and a lowermost gate stack; and
trench inner spacers (TISs) connected to the second inner spacers and extended up to the insides of the trenches,
wherein the trenches include first regions formed to extend in a first direction and second regions which are located on the bottom of the first regions and of which a cross section is formed to extend in a second direction orthogonal to the first direction.

2. The gate-all-around field effect transistor of claim 1, wherein the trenches include a first trench and a second trench positioned at a separation distance equal to or different from a width of the gate stacks.

3. The gate-all-around field effect transistor of claim 2, wherein the separation distance between the first trench and the second trench is larger than the widths of the gate stacks.

4. The gate-all-around field effect transistor of claim 1, wherein the first regions have a width equal to or different from that of the first inner spacers.

5. The gate-all-around field effect transistor of claim 4, wherein the first regions have a width larger than that of the second inner spacer.

6. The gate-all-around field effect transistor of claim 1, wherein the first regions have a width equal to or different from that of the second regions.

7. The gate-all-around field effect transistor of claim 6, wherein the second regions have a width larger than that of the first regions.

8. The gate-all-around field effect transistor of claim 1, wherein the trenches include a first trench and a second trench positioned at a separation distance larger than the widths of the gate stacks, and the second regions of the trenches have a width larger than that of the first regions.

9. The gate-all-around field effect transistor of claim 1, wherein the second regions include curved surface portions.

10. The gate-all-around field effect transistor of claim 1, wherein the trench inner spacers include:
first parts which are located within the first regions and fill at least a portion of the first regions; and
second parts which are located within the second regions and fill at least a portion of the second regions.

11. The gate-all-around field effect transistor of claim 10, wherein the second regions of the trenches have remaining parts of unetched sacrificial layers positioned in the lower portion thereof.

12. The gate-all-around field effect transistor of claim 1, further comprising Si epitaxial layers on the inner surface of the trenches.

13. The gate-all-around field effect transistor of claim 2, wherein a portion of the substrate located between the first trench and the second trench has a thickness that is the same as or different from that of other portion of the substrate.

14. The gate-all-around field effect transistor of claim 1, wherein the trench inner spacers include one or more insulating materials selected from the group consisting of SiO₂, Al₂O₃, HfO₂, ZrO₂, Si₃N₄, and perovskite oxide.

15. A method for manufacturing a gate-all-around field effect transistor, the method comprising the steps of:
patterning a first trench and a second trench on the top of one side of a substrate or a punch through stopper (PTS) on the substrate;
forming pluralities of channels and sacrificial layers alternately arranged on the substrate or punch through stopper (PTS);
forming a dummy gate;
vertically etching the channels and sacrificial layers to form a source region/a drain region;
etching at least a portion of the sacrificial layers in contact with the channels;
depositing an insulating material on the etched regions of the sacrificial layers to form inner spacers and trench inner spacers (TISs) connected to the inner spacers and formed to extend to the insides of the trenches;
forming the source region/drain region by a selective epitaxial growth process; and
forming a replacement metal gate,
wherein the first trench and the second trench are formed with a separation distance equal to or different from the widths of the gate stacks.

16. The method of claim 15, wherein the first trench and the second trench are formed with a separation distance larger than the widths of the gate stacks.

17. The method of claim 15, wherein the first trench or the second trench is formed to have a width that is the same as or a different from that of the inner spacers.

18. The method of claim 17, wherein the first trench or the second trench is formed to have a width larger than that of the inner spacers.

19. The method of claim 15, wherein the first trench or the second trench is formed to include a partially curved surface portion.

20. The method of claim 15, wherein a partial region of the outer cross section of the first trench or the second trench is etched during the step of etching at least a portion of the sacrificial layers.

21. The method of claim 15, wherein the remaining parts of the unetched sacrificial layers are located in the lower portion of the first trench or the second trench, and the trench inner spacers are formed to be positioned on the remaining parts.

22. The method of claim 15, further comprising a step of forming Si epitaxial layers on the inner surface of the first trench or the second trench by a selective epitaxial growth process after the step of patterning the trenches.

23. The method of claim 15, wherein during the step of forming the source region/drain region, the source region/drain region are formed to be in contact with at least a portion of the exposed end surface of the trench inner spacers.
